(19) United States
(12) Patent Application Publication
(10) Pub. No.: US 2026/0100231 A1
(43) Pub. Date: Apr. 9, 2026

(54) DYNAMIC PROGRAM PULSE WIDTHS FOR DIFFERENT SUB-BLOCKS IN A MEMORY DEVICE

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/310,714

(22) Filed: Aug. 26, 2025

Related U.S. Application Data
(60) Provisional application No. 63/704,845, filed on Oct. 8, 2024.

(51) Int. Cl. G11C 16/10; G11C 16/30; G11C 16/32

(52) U.S. Cl. CPC G11C 16/102; G11C 16/30; G11C 16/32

(57) ABSTRACT

A memory device includes a memory array with a plurality of blocks and control logic to initiate a program operation on one or more memory cells in a first sub-block of one of the plurality of blocks of the memory array. The control logic further identifies a categorization of the first sub-block, determines a corresponding program pulse width based on the categorization of the first sub-block, and causes a program voltage pulse having the corresponding program pulse width to be applied to the one or more memory cells during the program operation.

### RELATED APPLICATIONS

This application claims the benefit of priority from U.S. Provisional Ser. No. 63/704,845, filed Oct. 8, 2024, the entire contents of which are hereby incorporated by reference herein.

### TECHNICAL FIELD

Embodiments of the disclosure relate generally to memory sub-systems, and more specifically, relate to dynamic program pulse widths for different sub-blocks in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3 is a diagram illustrating a block of a memory array having multiple sub-blocks in accordance with some embodiments of the present disclosure.

FIG. 4 is a flow diagram of an example method of performing a program operation with dynamic program pulse widths for different sub-blocks in a memory device of a memory sub-system in accordance with some embodiments of the present disclosure.

FIG. 5 is a diagram illustrating waveforms with dynamic program pulse widths for different sub-blocks in a memory device in accordance with some embodiments of the present disclosure.

FIG. 6 is a block diagram of an example computer system in which embodiments of the present disclosure can operate.

### DETAILED DESCRIPTION

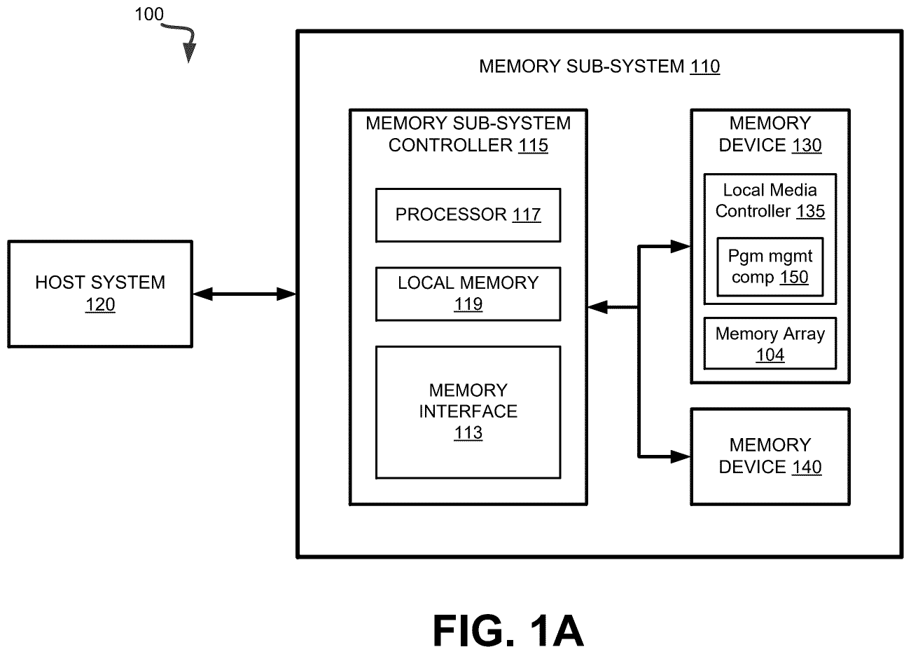

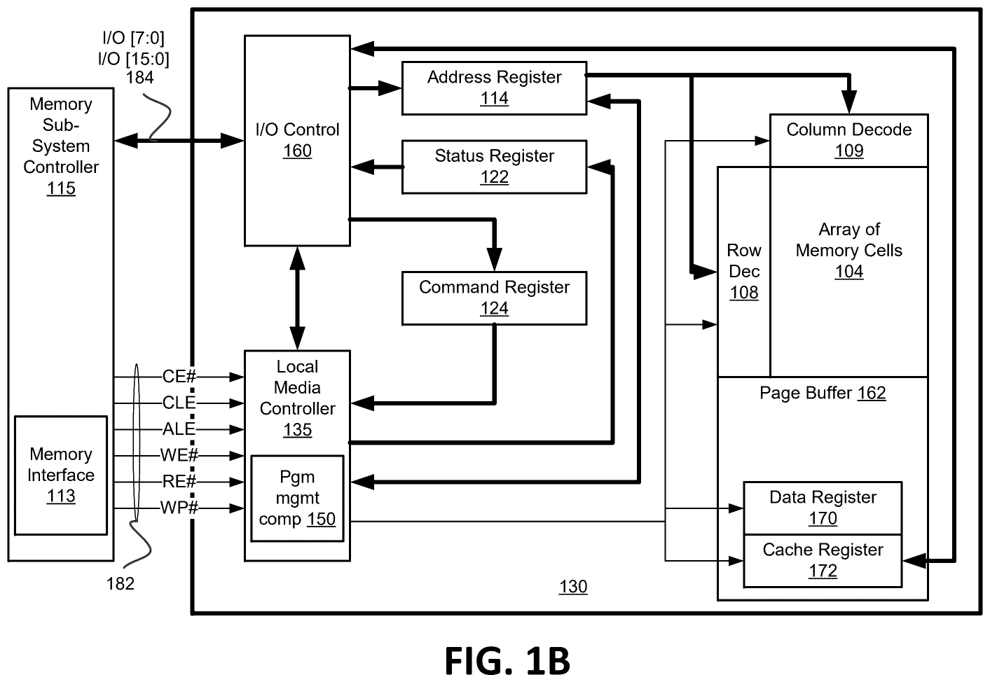

Aspects of the present disclosure are directed to dynamic program pulse widths for different sub-blocks in a memory device of a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high-density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bit lines) and rows (also hereinafter referred to as wordlines). A wordline can refer to one or more rows of memory cells of a memory device that are used with one or more bit lines to generate the address of each of the memory cells. The intersection of a bit line and wordline constitutes the address of the memory cell. A block hereinafter refers to a unit of the memory device used to store data and can include a group of memory cells, a wordline group, a wordline, or individual memory cells.

One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. Each data block can include a number of sub-blocks, where each sub-block is defined by an associated pillar (e.g., a vertical conductive trace) extending from a shared bitline. Since the sub-blocks can be accessed separately (e.g., to perform program or read operations), the data block can include a structure to selectively enable the pillar associated with a certain sub-block, while disabling the pillars associated with other sub-blocks. In one embodiment, this structure includes one or more select gate devices positioned at either or both ends of each pillar. Depending on a control signal applied, these select gate devices can either enable or disable the conduction of signals through the pillars. In one embodiment, the select gates devices associated with each pillar in the data block are controlled separately. Newer memory architectures have an ever-increasing number of sub-blocks (e.g., 4, 6, 8, or more sub-blocks per block), in order to increase the potential for parallel memory access operations. The increased number of sub-blocks, however, lead to an increased area (e.g., in the X and Y dimensions) of the memory device.

One solution to help reduce the size the of the memory device in the X and Y dimensions, is to use deintegrated select gate devices at the drain-end of the pillars (i.e., located at a portion of the pillar that is formed as a separate processing step from the rest of the pillar where core memory cells are located). For example, these deintegrated select gate devices can be formed in additional horizontal layers disposed above the rest of the memory array. The use of such deintegrated select gate devices can help decrease the size the of the memory device in the X and Y dimensions since physical cuts between the sub-blocks of a given block are not required. The additional of extra horizontal layers, however, may increase the overall height of the memory array (e.g., in the Z dimension). To account for the increased height, certain memory architectures decrease the height of each individual horizontal layer in the memory array (i.e., reduce the thickness of the metal layers that form access lines for the memory cells). The thinner metal layers have an increased electrical resistance, however, making it more difficult for electrical signals, such as a program voltage signal, to flow through the access lines. Accordingly, a longer program pulse width, which can be represented by a parameter T_pgm_pulse, may be needed to ensure that a program operation is successful and to reduce the error rate associated with the program operation. The longer program pulse width, however, increases the overall program time and hurts performance in the memory device.

Furthermore, as the number of sub-blocks per block of the memory device do increase, there are fabrication challenges that arise, which can impact memory device performance. For example, the diffusion of metal layers to form the access lines generally begins from the edges of a given block and moves toward the center. As such, there is the possibility that the thickness of the metal layers becomes uneven across different sub-blocks. For example, the outer-most sub-blocks (i.e., those nearer the edges of the block) may have resulting thicker metal layers, while the inner-most sub-blocks (i.e., those nearer the center of the block) may have resulting thinner metal layers. In addition, the reduced scaling of the horizontal layers, as described above, makes the diffusion less consistent. The thinner metal layers and inconsistent thickness can lead to a number of issues during operation of the memory device, such as degraded read disturb effects, degraded cycling, erase saturation, higher resistance, etc. As above, a longer program pulse width (i.e., T_pgm_pulse), may be used to improve performance associated with the program operation, at the expense of increased overall program time.

Conventional memory devices utilize that same program pulse width for all sub-blocks in a given block. Since programming data to at least some sub-blocks in the memory device is benefitted by using a longer program pulse width, that longer program pulse width is used when programming all sub-blocks in the memory device. This includes certain sub-blocks which do not necessarily require a longer program pulse width, such as those sub-blocks with thicker metal layers, and those sub-blocks closer to the edges of the block. Accordingly, the overall program time for those sub-blocks is increased unnecessarily.

Aspects of the present disclosure address the above and other deficiencies by implementing dynamic program pulse widths for different sub-blocks in a memory device of a memory sub-system. For example, when performing a program operation on memory cells in a given sub-block of a block of the memory device, control logic can identify a categorization of the sub-block and determine a corresponding program pulse width. In one embodiment, the categorization can be based on the physical position of the sub-block within the block (e.g., outer-most, middle, inner-most). In different embodiments, there can be any number of different categorizations, or the categorization can be based on different criteria. Each categorization can have a different corresponding program pulse width, which may be predefined according to the specific parameters of the memory device. For example, the outer-most sub-blocks may have a shorter program pulse width than the middle sub-blocks, which in turn have a shorter program pulse width than the inner-most sub-blocks. In different embodiments, two or more different categorizations can have the same corresponding program pulse width, or the relative widths can vary from those described in this example. Once the corresponding program pulse width is identified, the control logic can perform the program operation on the memory cells in the sub-block using the identified program pulse width.

Advantages of this approach include, but are not limited to, improved performance in the memory sub-system. The dynamic selection of a program pulse width based on the categorization of the sub-block being programmed ensures that an unnecessarily long program pulse width is not utilized when it is not warranted, but allows for increased program pulse widths to be used with other sub-blocks in order to reduce the associated error rate. This permits overall programming times in the memory device to be decreased and improves the overall quality of service provided to a host system.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface 113 that is responsible for handling interactions of memory sub-system controller 115 with the memory devices of memory sub-system 110, such as memory device 130. For example, the memory interface 113 can send memory access commands corresponding to requests received from host system 120 to memory device 130, such as program commands, read commands, or other commands. In addition, the memory interface 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein.

In one embodiment, local media controller 135 of memory device 130 includes program management component 150. Program management component 150 can implement dynamic program pulse widths for different sub-blocks in the memory array 104 of memory device 130. For example, when performing a program operation on memory cells in a given sub-block of a block of the memory device 130, program management component 150 can identify a categorization of the sub-block and determine a corresponding program pulse width. In one embodiment, the categorization can be based on the physical position of the sub-block within the block (e.g., outer-most, middle, inner-most). Each categorization can have a different corresponding program pulse width, which may be predefined according to the specific parameters of the memory device 130. For example, the outer-most sub-blocks may have a shorter program pulse width than the middle sub-blocks, which in turn have a shorter program pulse width than the inner-most sub-blocks. Once the corresponding program pulse width is identified, program management component 150 can perform the program operation on the memory cells in the sub-block using the identified program pulse width. Further details with regards to the operations of program management component 150 and are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes memory interface 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes program management component 150, which can implement dynamic program pulse widths for different sub-blocks in memory array 104, as described herein.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer 162 of the memory device 130. The page buffer 162 may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

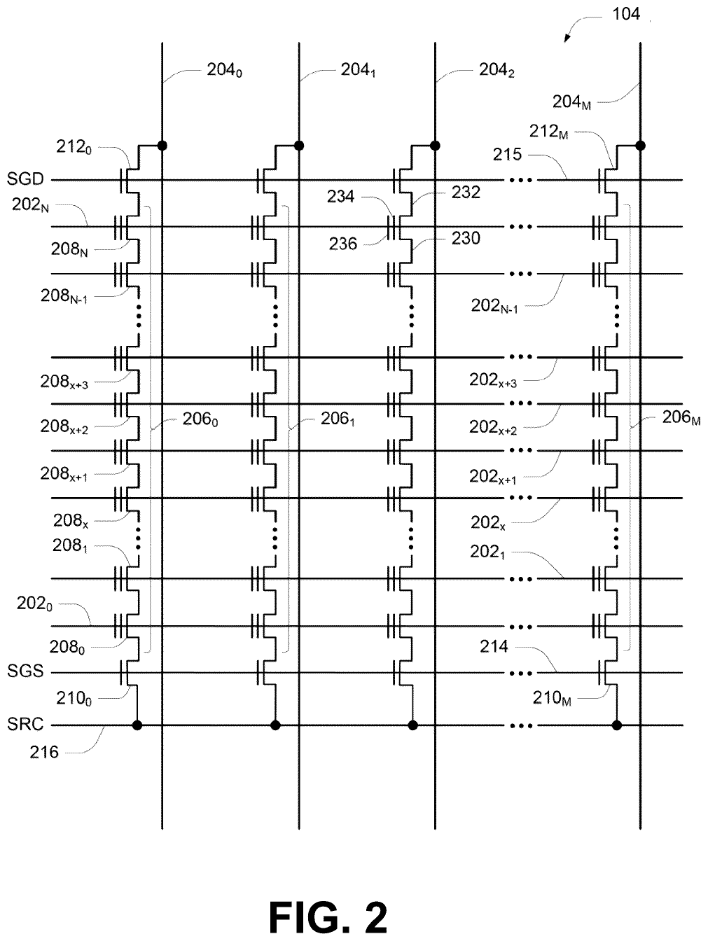

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bit lines 204₀ to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the array of memory cells 104 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

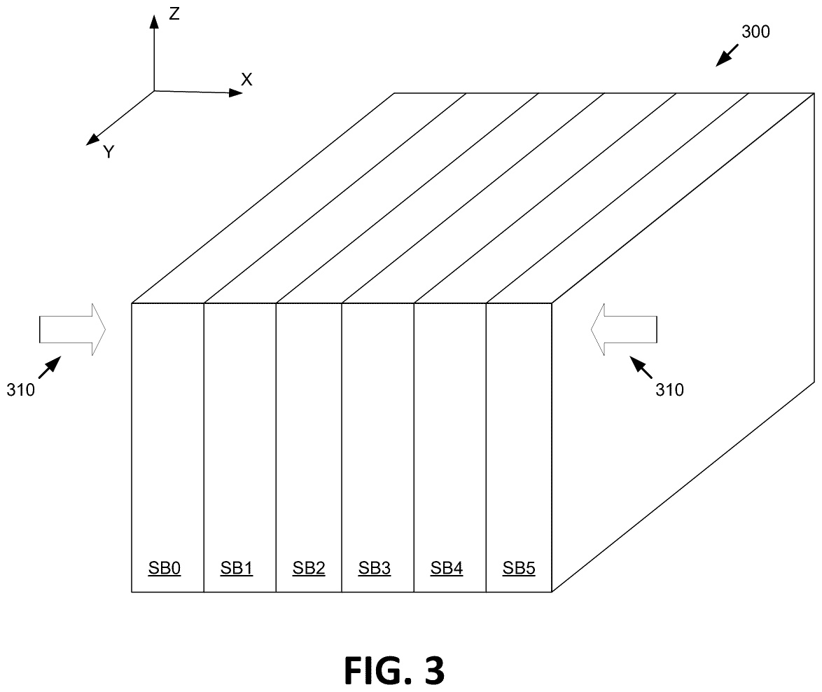

FIG. 3 is a diagram illustrating a block of a memory array having multiple sub-blocks in accordance with some embodiments of the present disclosure. Block 300 can be representative of any one of multiple blocks in memory array 104. As illustrated, block 300 can include a number of sub-blocks (e.g., SB0-SB5). The number of sub-blocks can vary depending on the implementation, but can include, for example, 4 sub-blocks, 6 sub-blocks, 8 sub-blocks, or some other number of sub-blocks. Each sub-block can include associated control circuitry, that allows the sub-blocks to be accessed separately from one other, such that concurrent memory access operations can be performed in parallel on different sub-blocks. The inclusion of additional sub-blocks can extend the footprint of the block 300 in the X dimension, while the inclusion of additional bitlines can extend the footprint of the block 300 in the Y dimension. Although not illustrated in FIG. 3, block 300 further includes a number of horizontal layers spanning across the multiple sub-blocks SB0-SB5. The inclusion of additional horizontal layers can extend the height of the block 300 in the Z dimension.

As described above, during fabrication of the memory device, metal films can be diffused through the horizontal layers of block 300 to form access lines for the memory cells in the multiple sub-blocks SB0-SB5. In one implementation, the diffusion 310 generally begins from the edges of block 300 (i.e., first contacting outer-most sub-blocks SB0 and SB5), and moves toward the center (i.e., through middle sub-blocks SB1 and SB4 towards the inner-most sub-blocks SB2 and SB3). As such, there is the possibility that the thickness of the metal layers becomes uneven across the different sub-blocks. In one embodiment, program management component 150 can utilize dynamic program pulse widths for the different sub-blocks in order to reduce the total programming time and improve performance in the memory device, as will be described in more detail below.

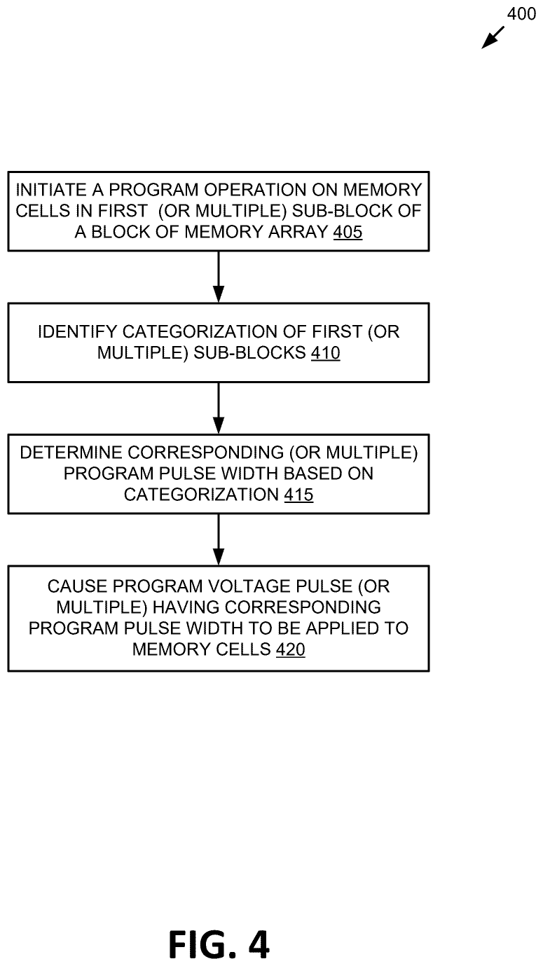

FIG. 4 is a flow diagram of an example method of performing a program operation with dynamic program pulse widths for different sub-blocks in a memory device of a memory sub-system in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by program management component 150 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, a program operation is initiated. For example, the processing logic (e.g., program management component 150) can initiate a program operation on one or more memory cells in a first sub-block of one of a plurality of blocks in a memory array 104. In one embodiment, the memory array 104 includes a plurality of memory cells formed at respective intersections of a plurality of wordlines and a plurality of bit lines. These memory cells can be grouped into a number of sub-blocks, such as sub-blocks SB0-SB5, as illustrated in FIG. 3. Depending on the embodiment, the program operation can be directed to memory cells in only a single sub-block, or in multiple sub-blocks of a block, such as block 300.

At operation 410, a sub-block categorization is identified. For example, the processing logic can identify a categorization of the first sub-block or of the multiple sub-blocks to which the program operation is directed. In one embodiment, the block 300 includes a number of sub-blocks, such as sub-blocks SB0-SB5, and each of the sub-blocks has a respective associated categorization. In one embodiment, the categorization of the sub-blocks is based on a physical location of the sub-blocks within the block 300. For example, the categorization can be an outer-most sub-block (e.g., SB0 or SB5) disposed at an edge of block 300 (i.e., an edge from which the diffusion 310 begins), an inner-most sub-block (e.g., SB2 or SB3) disposed at a center of block 300 (i.e., furthest from the edge), or a middle sub-block (e.g., SB1 or SB4) disposed between the outer-most sub-block and the inner-most sub-block of block 300. In other embodiments, there can be some other number of or different categorizations. For example, if a block were to have 8 sub-blocks, there could be multiple middle sub-blocks that either each had their own categorization or were grouped together in the same categorization. In one embodiment, the sub-blocks are associated with a given categorization during fabrication of the memory device 130, and the categorizations are stored in a local memory on memory device 130, from which they can be retrieved by program management component 150.

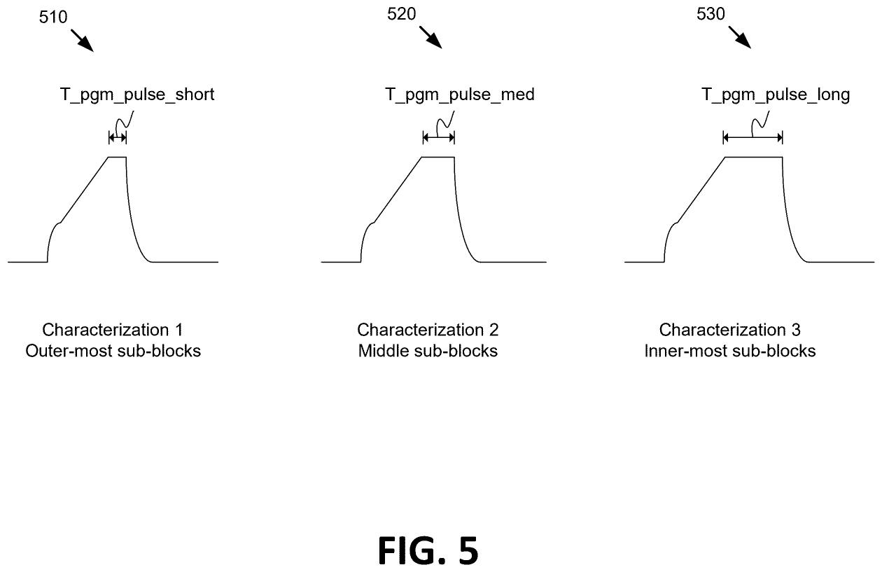

At operation 415, a corresponding program pulse width is determined. For example, the processing logic can determine a corresponding program pulse width or multiple program pulse widths for the sub-block(s) based on the identified categorization or categorizations. In one embodiment, each of the respective characterizations described above has a different corresponding program pulse width. In one embodiment, determining the corresponding program pulse width comprises determining a predefined period, based on the categorization, for which a program voltage pulse is to remain at a peak voltage level (i.e., the flattop of the program voltage pulse occurring after the signal ramps up to the peak voltage level and before it ramps back down again). FIG. 5 is a diagram illustrating waveforms with dynamic program pulse widths for different sub-blocks in a memory device in accordance with some embodiments of the present disclosure. In one embodiment, waveform 510 illustrates a short program pulse width (i.e., T_pgm_pulse_short), which may be associated with the characterization of the outer-most sub-blocks (e.g., SB0 and SB5), waveform 520 illustrates a medium program pulse width (i.e., T_pgm_pulse_med), which may be associated with the characterization of the middle sub-blocks (e.g., SB1 and SB4), and waveform 530 illustrates a long program pulse width (i.e., T_pgm_pulse_long), which may be associated with the characterization of the inner-most sub-blocks (e.g., SB2 and SB3). In one embodiment, the different program pulse widths are determined during fabrication of the memory device 130 and are stored in a local memory on memory device 130, from which they can be retrieved by program management component 150.

Referring again to FIG. 4, at operation 420, a program voltage pulse is applied. For example, the processing logic can cause a program voltage pulse, or multiple program voltage pulses, having the corresponding program pulse width(s) to be applied to the one or more memory cells during the program operation. In one embodiment, each of the programming pulses are separated by one or more verify operations, and are applied to access lines (e.g., wordlines) associated with selected memory cells to program the selected memory cells to respective target data states. After each programming pulse, one or more verify voltage levels are typically used to verify the programming of the selected memory cells. Programming typically uses many programming pulses in an incremental step pulse programming (ISPP) scheme, where each programming pulse is a single-level pulse that moves the memory cell threshold voltage by some amount. In one embodiment, the process logic can load a value indicating the corresponding program pulse width or widths determined at operation 415 into an associated register that controls the length of the predefined period for which the program voltage pulse is to remain at the peak voltage level (i.e., the T_pgm_pulse length). The processing logic can repeat this process for any number of different program voltage pulses to be applied during the program operation, each pulse having a corresponding program pulse width based on the categorization of the sub-block to which the program voltage pulse is being applied.

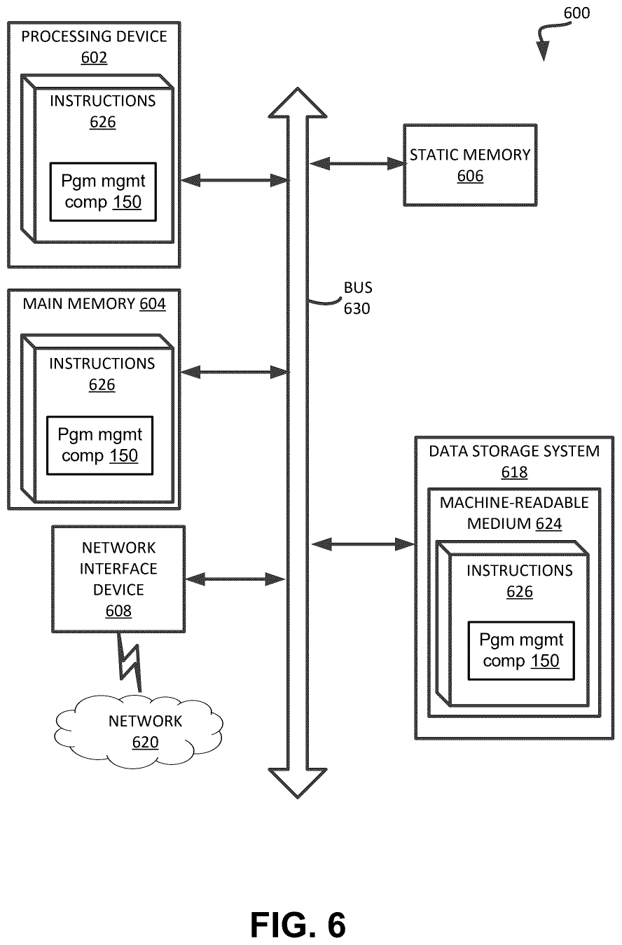

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to program management component 150 or local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein.

The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the instructions 626 include instructions to implement functionality corresponding to the program management component 150 of FIG. 1A. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of blocks; and
control logic, operatively coupled with the memory array, to perform operations comprising:
initiating a program operation on one or more memory cells in a first sub-block of one of the plurality of blocks of the memory array;
identifying a categorization of the first sub-block;
determining a corresponding program pulse width based on the categorization of the first sub-block; and
causing a program voltage pulse having the corresponding program pulse width to be applied to the one or more memory cells during the program operation.

2. The memory device of claim 1, wherein the categorization of the first sub-block is based on a physical location of the first sub-block within the one of the plurality of blocks.

3. The memory device of claim 1, wherein each of the plurality of blocks comprises a respective plurality of sub-blocks, and wherein each of the respective plurality of sub-blocks has a respective associated categorization.

4. The memory device of claim 3, wherein each respective associated categorization has a different corresponding program pulse width.

5. The memory device of claim 3, wherein each respective associated categorization comprises one of an outer-most sub-block disposed at an edge of one of the plurality of blocks, an inner-most sub-block disposed at a center of the one of the plurality of blocks, or a middle sub-block disposed between the outer-most sub-block and the inner-most sub-block of the one of the plurality of blocks.

6. The memory device of claim 1, wherein determining the corresponding program pulse width comprises determining a predefined period, based on the categorization of the first sub-block, for which the program voltage pulse is to remain at a peak voltage level.

7. The memory device of claim 1, wherein the causing the program voltage pulse having the corresponding program pulse width to be applied to the one or more memory cells during the program operation comprises loading a value indicating the corresponding program pulse width into an associated register.

8. A method comprising:
initiating a program operation on one or more memory cells in a first sub-block of one of a plurality of blocks of a memory device;
identifying a categorization of the first sub-block;
determining a corresponding program pulse width based on the categorization of the first sub-block; and
causing a program voltage pulse having the corresponding program pulse width to be applied to the one or more memory cells during the program operation.

9. The method of claim 8, wherein the categorization of the first sub-block is based on a physical location of the first sub-block within the one of the plurality of blocks.

10. The method of claim 8, wherein each of the plurality of blocks comprises a respective plurality of sub-blocks, and wherein each of the respective plurality of sub-blocks has a respective associated categorization.

11. The method of claim 10, wherein each respective associated categorization has a different corresponding program pulse width.

12. The method of claim 10, wherein each respective associated categorization comprises one of an outer-most sub-block disposed at an edge of one of the plurality of blocks, an inner-most sub-block disposed at a center of the one of the plurality of blocks, or a middle sub-block disposed between the outer-most sub-block and the inner-most sub-block of the one of the plurality of blocks.

13. The method of claim 8, wherein determining the corresponding program pulse width comprises determining a predefined period, based on the categorization of the first sub-block, for which the program voltage pulse is to remain at a peak voltage level.

14. The method of claim 8, wherein the causing the program voltage pulse having the corresponding program pulse width to be applied to the one or more memory cells during the program operation comprises loading a value indicating the corresponding program pulse width into an associated register.

15. A memory device comprising:
a memory array comprising a plurality of blocks; and
control logic, operatively coupled with the memory array, to perform operations comprising:
initiating a program operation on one or more memory cells in each of a plurality of sub-blocks of one of the plurality of blocks of the memory array;
identifying respective categorizations of each of the plurality of sub-blocks;
determining respective program pulse widths for each of the plurality of sub-blocks based on the respective categorizations; and
causing a plurality of program voltage pulses having the respective program pulse widths to be applied to the one or more memory cells during the program operation.

16. The memory device of claim 15, wherein the respective categorizations of each of the plurality of sub-blocks are based on physical locations of the plurality of sub-blocks within the one of the plurality of blocks.

17. The memory device of claim 15, wherein each respective categorization has a different corresponding program pulse width.

18. The memory device of claim 15, wherein each respective categorization comprises one of an outer-most sub-block disposed at an edge of one of the plurality of blocks, an inner-most sub-block disposed at a center of the one of the plurality of blocks, or a middle sub-block disposed between the outer-most sub-block and the inner-most sub-block of the one of the plurality of blocks.

19. The memory device of claim 15, wherein determining the respective program pulse widths for each of the plurality of sub-blocks comprises determining respective predefined periods, based on the respective categorizations, for which a corresponding program voltage pulse is to remain at a peak voltage level.

20. The memory device of claim 15, wherein the plurality of program voltage pulses having the respective program pulse widths to be applied to the one or more memory cells comprises loading respective values indicating the respective program pulse widths into an associated register.
